(19) United States
(12) Patent Application Publication
(10) Pub. No.: US 2003/0161180 A1
(43) Pub. Date: Aug. 28, 2003

(54) Shared bit lines in stacked MRAM arrays

(76) Inventors: Darrel R. Bloomquist, Meridian, ID (US); David H. McIntyre, Boise, ID (US); Judy Bloomquist, Meridian, ID (US)

Correspondence Address: HEWLETT-PACKARD COMPANY, Intellectual Property Administration, P.O. Box 272400, Fort Collins, CO, 80527-2400, US

(21) Appl. No.: 10/080,771

(22) Filed: Feb. 22, 2002

(51) Int. Cl. G11C 11/15

(52) U.S. Cl. 365/173

(57) ABSTRACT

A multi-layer random access memory device uses a shared conductive trace for writing to the MRAM memory cells. The MRAM has N (where N is greater than 1) stacked magnetic storage elements, where each of the N magnetic storage elements is operatively positioned between a different adjacent pair of N+1 stacked conductive traces. In one embodiment, the MRAM device includes a first conductive trace for generating a first magnetic field in response to a current applied to the first conductive trace, a second conductive trace for generating a second magnetic field in response to a current applied to the second conductive trace, and a third conductive trace for generating a third magnetic field in response to a current applied to the third conductive trace. A first magnetic storage element is operatively positioned between the first and second conductive traces and is adapted to store a bit of data as an orientation of magnetization and rotate its orientation of magnetization in response to the first and second magnetic fields generated by the first and second conductive traces. A second magnetic storage element is operatively positioned between the second and third conductive traces and is adapted to store a bit of data as an orientation of magnetization and rotate its orientation of magnetization in response to the second and third magnetic fields.

### THE FIELD OF THE INVENTION

The present invention generally relates to stacked magnetic random access memory (MRAM) arrays. More particularly, the present invention relates to stacked MRAM arrays which share bit lines between stacked memory cells.

### BACKGROUND OF THE INVENTION

A typical MRAM device includes an array of memory cells. The typical magnetic memory cell includes a layer of magnetic film in which the magnetization is alterable and a layer of magnetic film in which the magnetization is fixed or “pinned” in particular direction. The magnetic film having alterable magnetization may be referred to as a data storage layer and the magnetic film which is pinned may be referred to as a reference layer.

Conductive traces (commonly referred to as word lines and bit lines) are routed across the array of memory cells. Word lines extend along rows of the memory cells, and bit lines extend along columns of the memory cells. Located at each intersection of a word line and a bit line, each memory cell stores the bit of information as an orientation of a magnetization. Typically, the orientation of magnetization in the data storage layer aligns along an axis of the data storage layer that is commonly referred to as its easy axis. Typically, external magnetic fields are applied to flip the orientation of magnetization in the data storage layer along its easy axis to either a parallel or anti-parallel orientation with respect to the orientation of magnetization in the reference layer, depending on the desired logic state.

The orientation of magnetization of each memory cell will assume one of two stable orientations at any given time. These two stable orientations, parallel and anti-parallel, represent logical values of “1” and “0”. The orientation of magnetization of a selected memory cell may be changed by supplying current to a word line and a bit line crossing the selected memory cell. The currents create magnetic fields that, when combined, can switch the orientation of magnetization of the selected memory cell from parallel to anti-parallel or vice versa.

A selected magnetic memory cell is usually written by applying electrical currents to the particular word and bit lines that intersect at the selected magnetic memory cell. Typically, an electrical current applied to the particular bit line generates a magnetic field substantially aligned along the easy axis of the selected magnetic memory cell. The magnetic field aligned to the easy axis may be referred to as a longitudinal write field. An electrical current applied to the particular word line usually generates a magnetic field substantially perpendicular to the easy axis of the selected magnetic memory cell.

Typically, only the selected magnetic memory cell receives both the longitudinal and the perpendicular write fields. Other magnetic memory cells coupled to the particular word line usually receive only the perpendicular write field. Other magnetic memory cells coupled to the particular bit line usually receive only the longitudinal write field.

The magnitudes of the longitudinal and the perpendicular write fields are usually chosen to be high enough so that the selected magnetic memory cell switches its logic state when subjected to both longitudinal and perpendicular fields, but low enough so that the other magnetic memory cells which are subject only to either the longitudinal or the perpendicular write field do not switch. An undesirable switching of a magnetic memory cell that receives only the longitudinal or the perpendicular write field is commonly referred to as half-select switching.

Because the word lines and the bit lines operate in combination to switch the orientation of magnetization of the selected memory cell (i.e., to write the memory cell), the word lines and a bit lines can be collectively referred to as write lines. Additionally, the write lines can also be used to read the logic values stored in the memory cell.

FIG. 1 illustrates a top plan view of a simplified prior art MRAM array 100. The array 100 includes memory cells 120, word lines 130, and bit lines 132. The memory cells 120 are positioned at each intersection of a word line 130 with a bit line 132. Typically, the word lines 130 and bit lines 132 are arranged in orthogonal relation to one another and the memory cells 120 are positioned in between the write lines (130,132), as illustrated in FIG. 1b. For example, the bit lines 132 can be positioned above the memory cells 120 and the word lines 130 can be positioned below.

FIGS. 2a through 2c illustrate the storage of a bit of data in a single memory cell 120. In FIG. 2a, the memory cell 120 includes an active magnetic data film 122 and a pinned magnetic film 124 which are separated by a dielectric region 126. The orientation of magnetization in the active magnetic data film 122 is not fixed and can assume two stable orientations is shown by arrow M₁. On the other hand, the pinned magnetic film 124 has a fixed orientation of magnetization shown by arrow M₂. The active magnetic data film 122 rotates its orientation of magnetization in response to electrical currents applied to the write lines (130,132, not shown) during a write operation to the memory cell 120. The first logic state of the data bit stored in as memory cell 120 is indicated when M₁and M₂ are parallel to each other as illustrated in FIG. 2b. For instance, when M₁ and M₂ are parallel a logic “1” state is stored in the memory cell 120. Conversely, a second logic state is indicated when M₁ and M₂ are anti-parallel to each other as illustrated in FIG. 2c. Similarly, when M₁ and M₂ are anti-parallel a logic “0” state is stored in the memory cell 120. In FIGS. 2b and 2c the dialectic region 126 has been omitted. Although FIGS. 2a through 2c illustrate the active magnetic data film 122 positioned above the pinned magnetic film 124, the pinned magnetic film 124 can be positioned above the active magnetic data film 122.

The resistance of the memory cell 120 differs according to the orientations of M₁ and M₂. When M₁ and M₂ are anti-parallel, i.e., the logic “0” state, the resistance of the memory cell 120 is at its highest. On the other hand, the resistance of the memory cell 120 is at its lowest when the orientations of M₁ and M₂ are parallel, i.e., the logic “1” state. As a consequence, the logic state of the data bit stored in the memory cell 120 can be determined by measuring its resistance. The resistance of the memory cell 120 is reflected by a magnitude of a sense current 123 (referring to FIG. 2a) that flows in response to read voltages applied to the write lines (130,132).

In FIG. 3, the memory cell 120 is positioned between the write lines (130,132). The active and pinned magnetic films (122,124) are not shown in FIG. 3. The orientation of magnetization of the active magnetic data film 122 is rotated in response to a current Iₓ that generates a magnetic field H_{y} and a current I_{y} that generates a magnetic field Hₓ. The magnetic fields Hₓ and H_{y} act in combination to rotate the orientation of magnetization of the memory cell 120.

FIG. 4a shows a cross-sectional view taken along line 4a-4a in FIG. 3, while FIG. 4b illustrates a similar cross sectional view of a stacked prior art MRAM device. As can be seen in FIG. 4b, stacked prior art MRAM devices utilized two or more identical MRAM arrays in a stacked configuration and separated by a dielectric material (not shown). As can be seen, stacked prior art MRAM devices require two additional conductive trace layers (130, 132) for each MRAM layer. This means twice as many masking steps are required to generate a MRAM device having two stacked memory cells 120, three times as many masking steps are required to generate the MRAM device having three stacked memory cells 120, etc. In addition, stacked prior art MRAM devices also occupy more space, as the additional conductive layers and separating dielectric layers each contribute to the overall thickness of the device. Because space is often limited, smaller devices are typically preferred.

Therefore, what is needed is an MRAM device which requires a reduced number of steps to generate a stacked MRAM array, thereby simplifying the manufacturing process and reducing the size of the stacked MRAM array.

### SUMMARY OF THE INVENTION

The present invention provides a multi-layer random access memory device which uses a shared conductive trace for writing to the MRAM memory cells. The inventive MRAM device includes a first conductive trace for generating a first magnetic field in response to a current applied to the first conductive trace, a second conductive trace for generating a second magnetic field in response to a current applied to the second conductive trace, and a third conductive trace for generating a third magnetic field in response to a current applied to the third conductive trace. A first magnetic storage element is operatively positioned between the first and second conductive traces and is adapted to store a bit of data as an orientation of magnetization and rotate its orientation of magnetization in response to the first and second magnetic fields generated by the first and second conductive traces. A second magnetic storage element is operatively positioned between the second and third conductive traces and is adapted to store a bit of data as an orientation of magnetization and rotate its orientation of magnetization in response to the second and third magnetic fields.

The invention is applicable to any multi-layer random access memory having N (where N is greater than 1) stacked magnetic storage elements, where each of the N magnetic storage elements is operatively positioned between a different adjacent pair of the N+1 stacked conductive traces.

### BRIEF DESCRIPTION OF THE DRAWINGS

FIGS. 1a and 1b are top and profile views of a prior art MRAM array.

FIGS. 2a through 2c are profile and side views of a prior art MRAM memory cell illustrating an orientation of magnetization of active and reference magnetic films.

FIG. 3 is a profile view of a prior art memory cell.

FIG. 4a is a cross-sectional view of a prior art MRAM device taken along line 4a-4a of FIG. 3.

FIG. 4b is a cross-sectional representation of a prior art stacked MRAM device.

FIG. 5 is a perspective view illustrating one exemplary embodiment of a MRAM array according to the present invention.

FIG. 6 is a cross-sectional view taken along line 6-6 of FIG. 5.

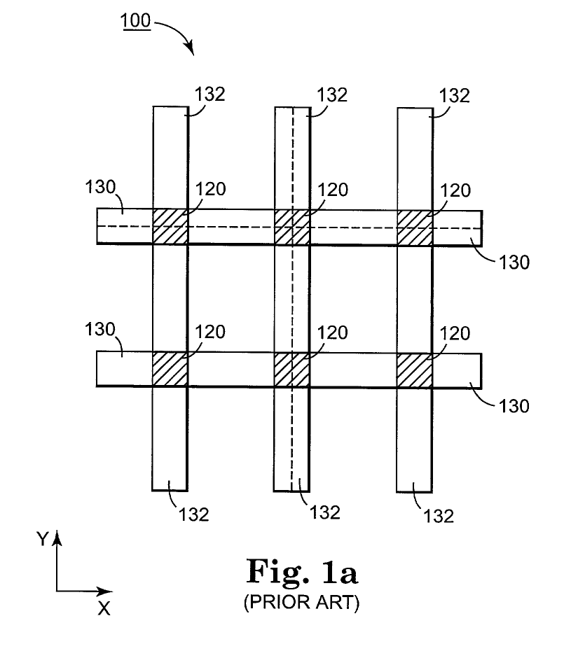

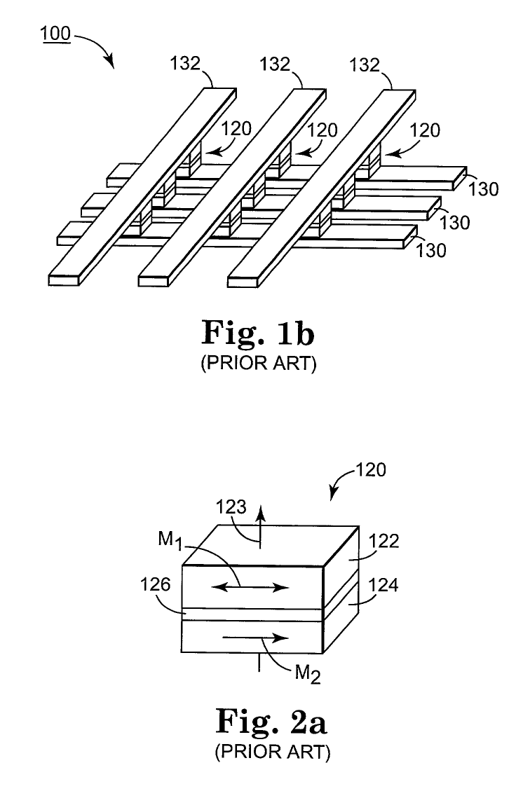

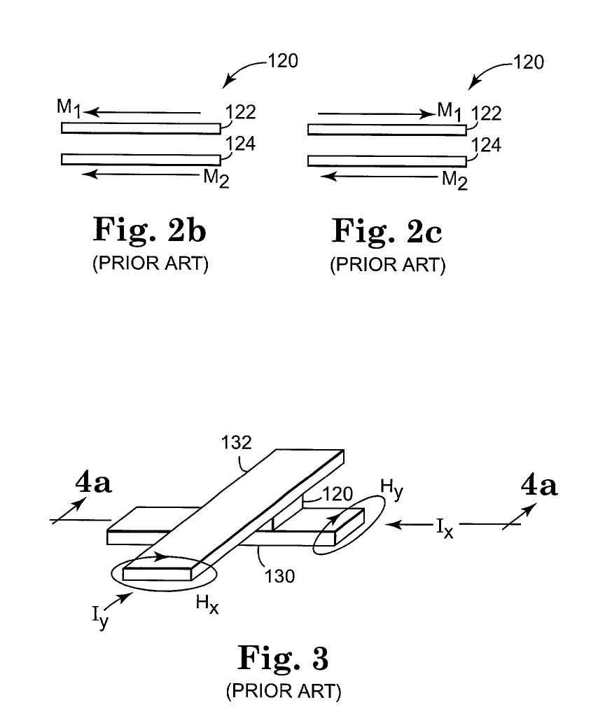

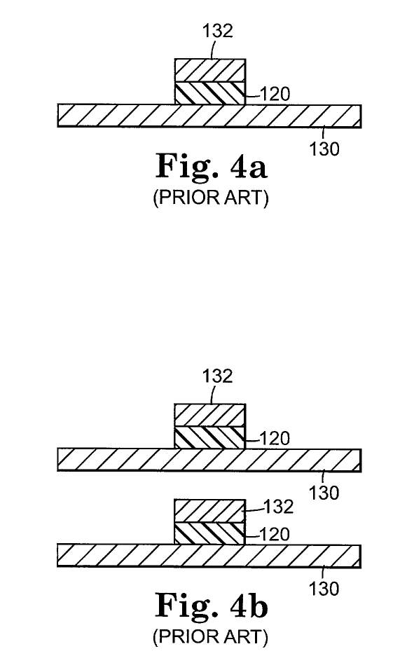

### DESCRIPTION OF THE PREFERRED EMBODIMENTS

In the following detailed description of the preferred embodiments, reference is made to the accompanying drawings which form a part hereof, and in which is shown by way of illustration specific embodiments in which the invention may be practiced. It is to be understood that other embodiments may be utilized and structural or logical changes may be made without departing from the scope of the present invention. The following detailed description, therefore, is not to be taken in a limiting sense, and the scope of the present invention is defined by the appended claims.

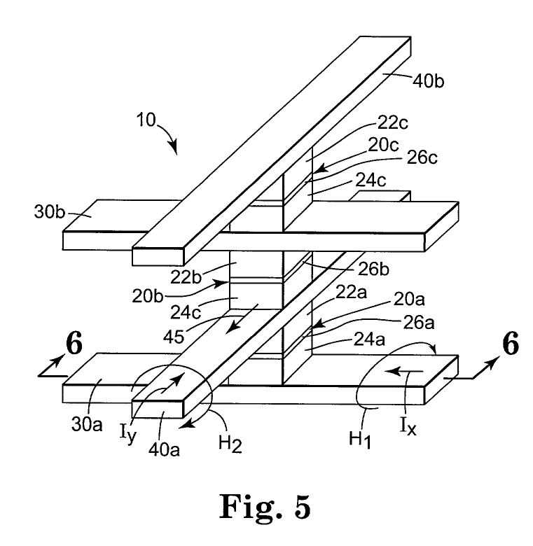

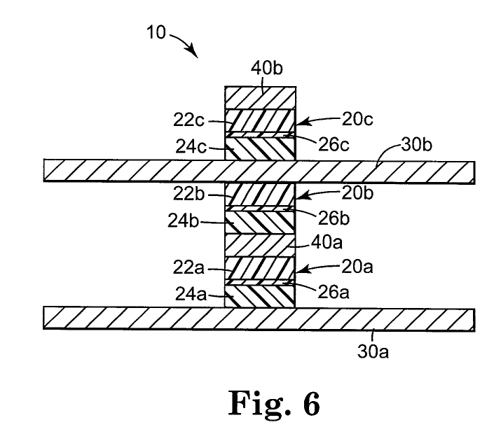

FIGS. 5 and 6 illustrate a section of a stacked magnetic random access memory (MRAM) 10 according to the present invention. The MRAM 10 includes an array of stacked memory cells 20a, 20b, 20c, each including an active magnetic data film 22a, 22b, 22c which functions as a data storage layer, a pinned magnetic film 24a, 24b, 24c which functions as a reference layer, and a dielectric material 26a, 26b, 26c which acts as a tunnel barrier between the data storage layer and the reference layer. This structure of a magnetic memory cell may be referred to as a spin tunneling device in that electrical charge migrates through the tunnel barrier during read operations. This electrical charge migration through the tunnel barrier is due to a phenomenon known as spin tunneling and occurs when a read voltage is applied to a magnetic memory cell. In an alternative embodiment, a giant magneto-resistive (GMR) structure may be used in the magnetic memory cells 20.

The MRAM 10 also includes an array of conductive word lines 30a, 30b and conductive bit lines 40a, 40b that enable read and write access to the magnetic memory cells 20a, 20b, 20c.

The magnetic memory cells 20a-20c are formed so that they will have an easy axis 45 which is substantially parallel to the conductors 40a, 40b. The conductors 30a, 30b are formed so that their general direction or orientation is substantially orthogonal to the conductors 40a, 40b. These geometries may be formed using known magnetic film processing techniques including photolithography, masking and etching.

It will be noted that the magnetic memory cells 20a, 20b, 20c share word line 30b and bit line 40a, which is distinctively different from prior art stacked MRAM devices. Specifically, memory cell 20a is written to by word line 30a and bit line 40a; memory cell 20b is written to by word line 30b and bit line 40a; and memory cell 20c is written to by word line 30b and bit line 40b. This sharing of conductive traces both reduces the number of steps required to manufacture the stacked MRAM device and reduces the overall thickness of the device.

The logic states of the magnetic memory cells 20a-20c are manipulated by applying electrical currents to the conductors 30a, 30b and 40a, 40b in the traditional manner. For example, the magnetic memory cell 20a is written by applying electrical currents to the conductors 30a and 40a that intersect at the magnetic memory cell 20a. The electrical current Iₓ applied to the conductor 30a in one direction causes a magnetic field (H₁) in the magnetic memory cell 20a according to the right-hand rule. Similarly, the electrical current I_{y} applied to the conductor 40a in one direction causes a magnetic field (H₂) in the magnetic memory cells 20a according to the right-hand rule. Memory cells 20b and 20c are spaced far enough from the pair of conductive traces 30a, 40a such that the logic states of memory cells 20b and 20c are not affected by the magnetic fields H₁ and H₂.

Although a stacked MRAM device having three memory cells and four conductive traces has been shown in FIGS. 5 and 6, the principles described herein are applicable to any number of stacked memory cells and conductive traces. Specifically, a stacked MRAM device having N stacked memory cells and N+1 stacked conductive traces may be constructed using the principles described herein.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiments shown and described without departing from the scope of the present invention. Those with skill in the mechanical, electromechanical and electrical arts will readily appreciate that the present invention may be implemented in a very wide variety of embodiments. This application is intended to cover any adaptations or variations of the preferred embodiments discussed herein. Therefore, it is manifestly intended that this invention be limited only by the claims and the equivalents thereof.

What is claimed is:

1. A multi-layer random access memory, comprising:
a first conductive trace for generating a first magnetic field in response to a current applied to the first conductive trace;
a second conductive trace for generating a second magnetic field in response to a current applied to the second conductive trace;
a third conductive trace for generating a third magnetic field in response to a current applied to the third conductive trace;
a first magnetic storage element operatively positioned between the first and second conductive traces, wherein the first magnetic storage element is adapted to store a bit of data as an orientation of magnetization and rotate the orientation of magnetization in response to the first and second magnetic fields; and
a second magnetic storage element operatively positioned between the second and third conductive traces, wherein the second magnetic storage element is adapted to store a bit of data as an orientation of magnetization and rotate the orientation of magnetization in response to the second and third magnetic fields.

2. The multi-layer random access memory of claim 1, further comprising:
a fourth conductive trace for generating a fourth magnetic field in response to a current applied to the fourth conductive trace; and
a third magnetic storage element operatively positioned between the third and fourth conductive traces, wherein the third magnetic storage element is adapted to store a bit of data as an orientation of magnetization and rotate the orientation of magnetization in response to the third and fourth magnetic fields.

3. The multi-layer random access memory of claim 1, wherein the first and second magnetic storage elements each comprise a storage layer having an easy axis.

4. The multi-layer random access memory of claim 3, wherein the first magnetic field is substantially parallel with the easy axis of the first magnetic storage element.

5. The multi-layer random access memory of claim 3, wherein the second magnetic field is substantially perpendicular to the easy axis of the first and second magnetic storage elements.

6. The multi-layer random access memory of claim 3, wherein the third magnetic field is substantially parallel to the easy axis of the second magnetic storage element.

7. The multi-layer random access memory of claim 1, wherein the first and second magnetic storage elements are spin tunneling devices.

8. The multi-layer random access memory of claim 1, wherein the first and second magnetic storage elements are giant magneto-resistive devices.

9. The multi-layer random access memory of claim 1, wherein alternate conductive traces are generally perpendicular to each other.

10. A multi-layer random access memory, comprising:
N+1 stacked conductive traces for generating N+1 magnetic fields in response to a current applied to each conductive trace; and
N stacked magnetic storage elements, wherein each one of the N magnetic storage elements is operatively positioned between a different adjacent pair of the N+1 stacked conductive traces, and wherein each magnetic storage element is adapted to store a bit of data as an orientation of magnetization and rotate the orientation of magnetization in response to the magnetic fields of the adjacent pair of conductive traces; where N is greater than 1.

11. The multi-layer random access memory of claim 10, wherein the magnetic storage elements each comprise a storage layer having an easy axis.

12. The multi-layer random access memory of claim 11, wherein the magnetic field of one conductor of each adjacent pair of conductive traces is substantially parallel with the easy axis of the magnetic storage element positioned between the adjacent pair of conductive traces.

13. The multi-layer random access memory of claim 11, wherein the magnetic field of one conductor of each adjacent pair of conductive traces is substantially perpendicular with the easy axis of the magnetic storage element positioned between the adjacent pair of conductive traces.

14. The multi-layer random access memory of claim 10, wherein the magnetic storage elements are spin tunneling devices.

15. The multi-layer random access memory of claim 10, wherein the magnetic storage elements are giant magneto-resistive devices.

16. The multi-layer random access memory of claim 10, wherein alternate conductive traces are generally perpendicular to each other.
